(19) United States
(12) Patent Application Publication
(10) Pub. No.: US 2014/0345674 A1
(43) Pub. Date: Nov. 27, 2014

(54) MOISTURE INGRESS RESISTANT PHOTOVOLTAIC MODULE

(71) Applicant: Silevo, Inc., Fremont, CA (US)

(72) Inventors: Bobby Yang, Los Altos Hills, CA (US); Jiunn Benjamin Heng, San Jose, CA (US); Jianming Fu, Palo Alto, CA (US); Zheng Xu, Pleasanton, CA (US)

(21) Appl. No.: 14/286,823

(22) Filed: May 23, 2014

Related U.S. Application Data
(60) Provisional application No. 61/827,429, filed on May 24, 2013.

(51) Int. Cl. H01L 31/048; H01L 31/18

(52) U.S. Cl. CPC H01L 31/048; H01L 31/18
USPC 136/251; 438/66

(57) ABSTRACT

One embodiment of the present invention provides a photovoltaic (PV) module. The PV module includes a front-side glass cover facing sunlight, a plurality of interconnected PV cells situated below the glass cover, a plurality of bussing wires electrically coupled to the PV cells, and a back-sheet situated below the PV cells. The back-sheet comprises a metal layer sandwiched between a top and a bottom insulation layers. The back-sheet comprises a cut slot to facilitate the bussing wires to thread through the cut slot to reach a junction box situated below the back-sheet. The PV module further comprises one or more insulation layers inserted between the bussing wires and sidewalls of the cut slot in the back-sheet. The insulation layers are configured to insulate the bussing wires to the metal layer in the back-sheet.

### RELATED APPLICATION

This application claims the benefit of U.S. Provisional Application No. 61/827,429, Attorney Docket Number SSP13-1003PSP, entitled “Photovoltaic Module That Is Moisture Ingress Resistant,” by inventors Bobby Yang, Jiunn Benjamin Heng, Jianming Fu, and Zheng Xu, filed 24 May 2013.

### COLOR DRAWINGS

The patent or application file contains at least one drawing executed in color. Copies of this patent or patent application publication with color drawing(s) will be provided by the Office upon request and payment of the necessary fee.

### BACKGROUND

1. Field

This disclosure is generally related to the fabrication of solar modules. More specifically, this disclosure is related to fabrication of a solar module that is resistant to moisture ingress.

2. Related Art

The negative environmental impact of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi-junction structure includes multiple single-junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit.

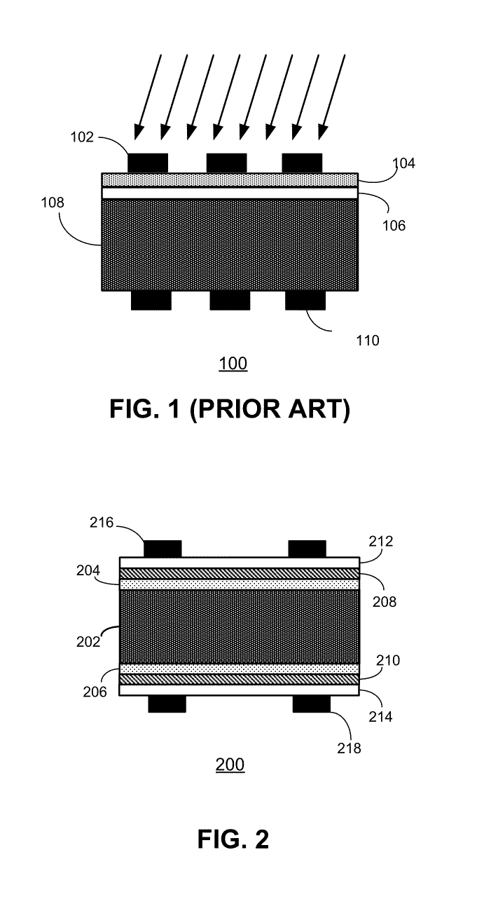

For homojunction solar cells, minority-carrier recombination at the cell surface due to the existence of dangling bonds can significantly reduce the solar cell efficiency; thus, a good surface passivation process is needed. In addition, the relatively thick, heavily doped emitter layer, which is formed by dopant diffusion, can drastically reduce the absorption of short wavelength light. Comparatively, heterojunction solar cells, such as Si heterojunction (SHJ) solar cells, are advantageous. FIG. 1 presents a diagram illustrating an exemplary SHJ solar cell (prior art). SHJ solar cell 100 includes front grid electrode 102, a heavily doped amorphous-silicon (a-Si) emitter layer 104, an intrinsic a-Si layer 106, a crystalline-Si substrate 108, and back grid electrode 110. Arrows in FIG. 1 indicate incident sunlight. Because there is an inherent bandgap offset between a-Si layer 106 and crystalline-Si (c-Si) layer 108, a-Si layer 106 can be used to reduce the surface recombination velocity by creating a barrier for minority carriers. The a-Si layer 106 also passivates the surface of crystalline-Si layer 108 by repairing the existing Si dangling bonds. Moreover, the thickness of heavily doped a-Si emitter layer 104 can be much thinner compared to that of a homojunction solar cell. Thus, SHJ solar cells can provide a higher efficiency with higher open-circuit voltage (V_{oc}) and larger short-circuit current (J_{sc}).

When fabricating solar cells, a layer of transparent conducting oxide (TCO) is often deposited on the a-Si emitter layer to form an ohmic contact. However, compared with traditional diffusion-based solar cells, the TCO-based SHJ solar cells are more susceptible to moisture ingress. Not only do they tend to lose their material properties when exposed to moisture, they may also serve as a medium through which moisture can reach the junction of the solar cell, thereby degrading the cell performance drastically.

### SUMMARY

One embodiment of the present invention provides a photovoltaic (PV) module. The PV module includes a front-side glass cover facing sunlight, a plurality of interconnected PV cells situated below the glass cover, a plurality of bussing wires electrically coupled to the PV cells, and a back-sheet situated below the PV cells. The back-sheet comprises a metal layer sandwiched between a top insulation layer and a bottom insulation layer. The back-sheet comprises a cut slot to facilitate the bussing wires to thread through the cut slot to reach a junction box situated below the back-sheet. The PV module further comprises one or more insulation layers inserted between the bussing wires and sidewalls of the cut slot in the back-sheet. The insulation layers are configured to insulate the bussing wires to the metal layer in the back-sheet.

In a variation on the embodiment, the insulation layers in the back-sheet include one or more of: polyethylene terephthalate (PET), Fluoropolymer, polyvinyl fluoride (PVF), and polyamide; and the metal layer in the back-sheet comprises Al.

In a further variation, the back-sheet includes one or more of: a dyMat APYE® (registered trademark of Coveme of Bologna, Italy) back-sheet, a Protekt® Al back-sheet made by Madico, Inc., and an Al-based back-sheet made by Isovolta Group or Dunmore Corporation.

In a variation on the embodiment, the one or more insulation layers include at least one of: dielectric tape, a tube made of dielectric materials, a non-metal partial back-sheet, and a partial back-sheet with a metal interlayer.

In a further variation, the dielectric tape includes Kapton® tape.

In a further variation, the tube includes at least one of: a polyethylene terephthalate (PET) tube and a polyvinyl fluoride (PVF) tube.

In a further variation, the non-metal partial back-sheet includes a Protekt® (registered trademark of Madico, Inc. of Woburn, Mass.) back-sheet or a Tedlar® (registered trademark of E. I. du Pont de Nemours and Company of Wilmington, Del.) back-sheet.

In a variation on the embodiment, the PV module further comprises an additional partial back-sheet situated between the PV cells and bussing wires at a location where the bussing wires thread through the cut slot. The additional partial back-sheet includes a metal interlayer situated between a top insulation layer and a bottom insulation layer, and the additional partial back-sheet is configured to: insulate the bussing wires to the backside of the solar cells and block potential moisture ingress from the cut slot in the back-sheet.

In a further variation, the additional partial back-sheet includes an Al interlayer.

In a variation on the embodiment, the PV cells include at least one double-sided tunneling junction solar cell.

In a variation on the embodiment, the PV cells and the bussing wires are encapsulated between the front-side glass cover and the back-sheet during a lamination process, forming a laminated structure.

In a further variation, encapsulating the PV cells and the bussing wires involves using a low moisture vapor transmission rate (MVTR) encapsulant that comprises one or more of: polyolefin and ionomer.

In a further variation, the PV module further comprises a metal frame configured to hold the laminated structure.

In a further variation, the metal frame is sufficiently large to ensure a predetermined minimum distance is maintained between corners and edges of the laminated structure and the metal frame, thereby facilitating application of insulation materials with sufficient thickness.

In a further variation, corners of the laminated structure are wrapped with one or more layers of dielectric tape.

In a variation on the embodiment, the PV cells include one or more of: a transparent conducting oxide (TCO) layer acting as an electrode and an anti-reflecting coating (ARC) layer.

### BRIEF DESCRIPTION OF THE FIGURES

FIG. 1 presents a diagram illustrating an exemplary SHJ solar cell (prior art).

FIG. 2 presents a diagram illustrating an exemplary double-sided tunneling junction solar cell, in accordance with an embodiment of the present invention.

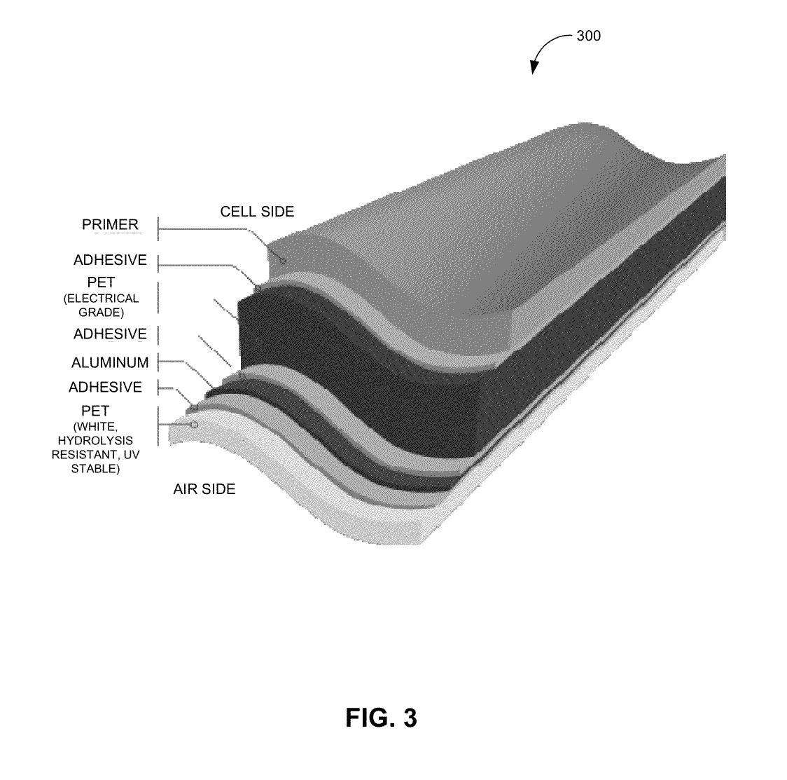

FIG. 3 presents a diagram illustrating the structure of an exemplary back-sheet with an Al interlayer.

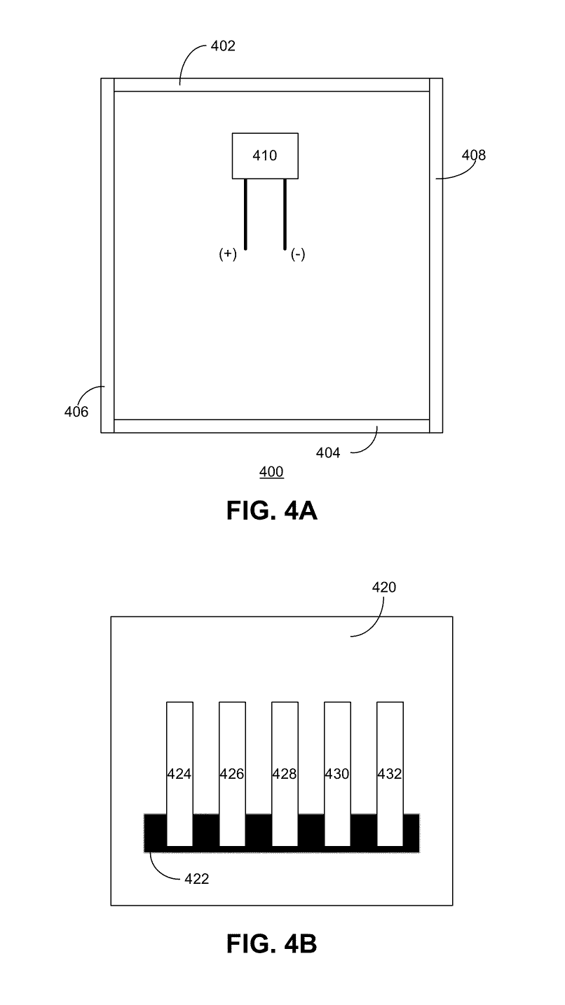

FIG. 4A presents a diagram illustrating the backside of a PV module.

FIG. 4B presents a diagram illustrating a scenario where bussing wires thread through a rectangular slot on the back-sheet, in accordance with an embodiment of the present invention.

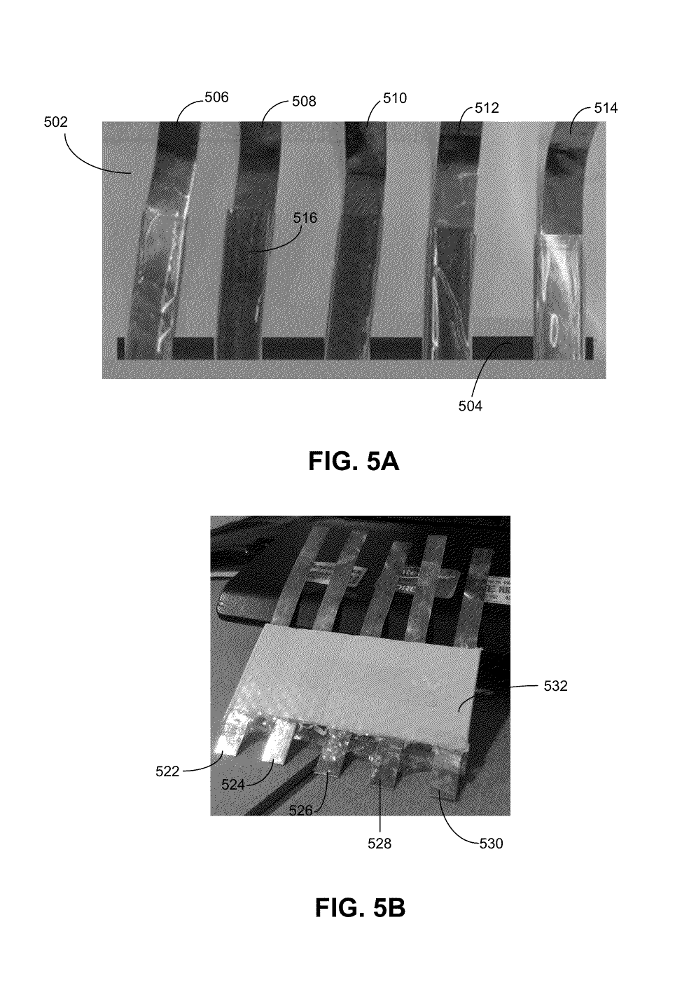

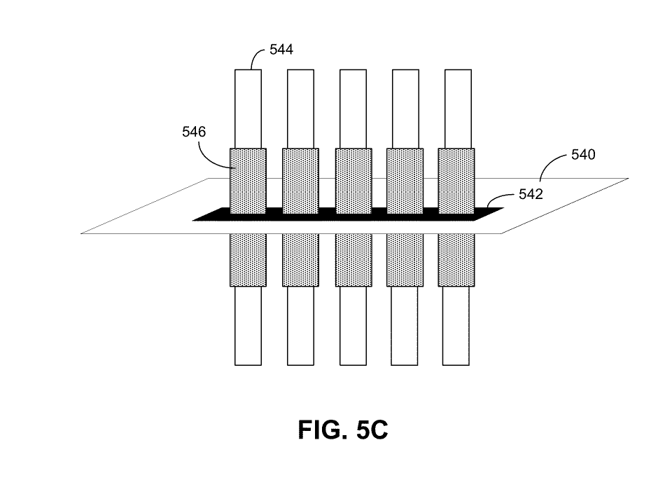

FIG. 5A presents a diagram illustrating a scenario where layers of dielectric tape wrap around metal bussing wires, in accordance with an embodiment of the present invention.

FIG. 5B presents a diagram illustrating a scenario where metal bussing wires are laminated within one or more layers of back-sheets that do not have an Al interlayer, in accordance with an embodiment of the present invention.

FIG. 5C presents a diagram illustrating a scenario where insulation tubing is slipped over metal bussing wires, in accordance with an embodiment of the present invention.

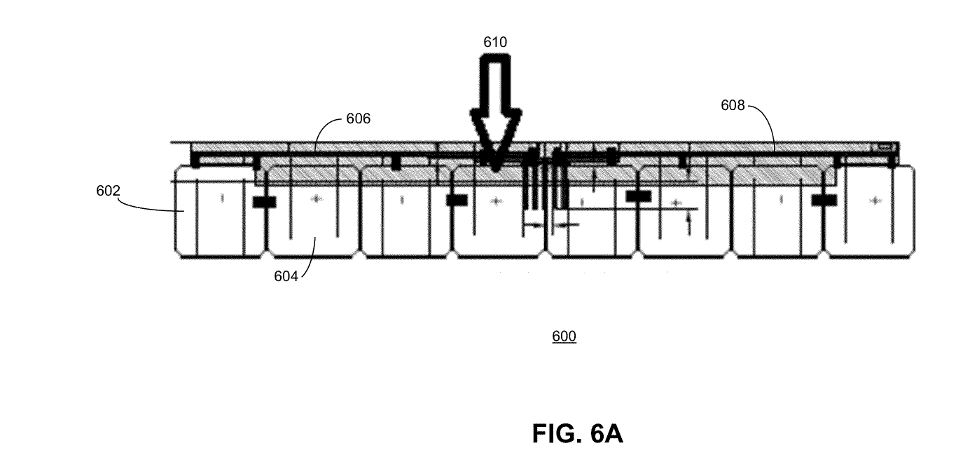

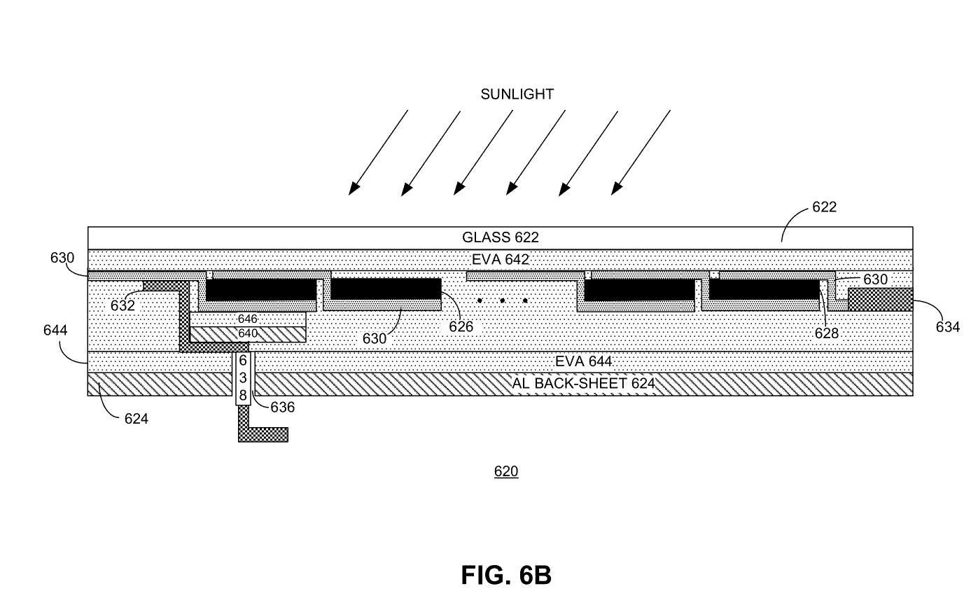

FIG. 6A presents a diagram illustrating an internal circuit assembly insulation layer placed between the bussing wires and the backside of the solar cells.

FIG. 6B presents a diagram illustrating the side view of a PV module, in accordance with an embodiment of the present invention.

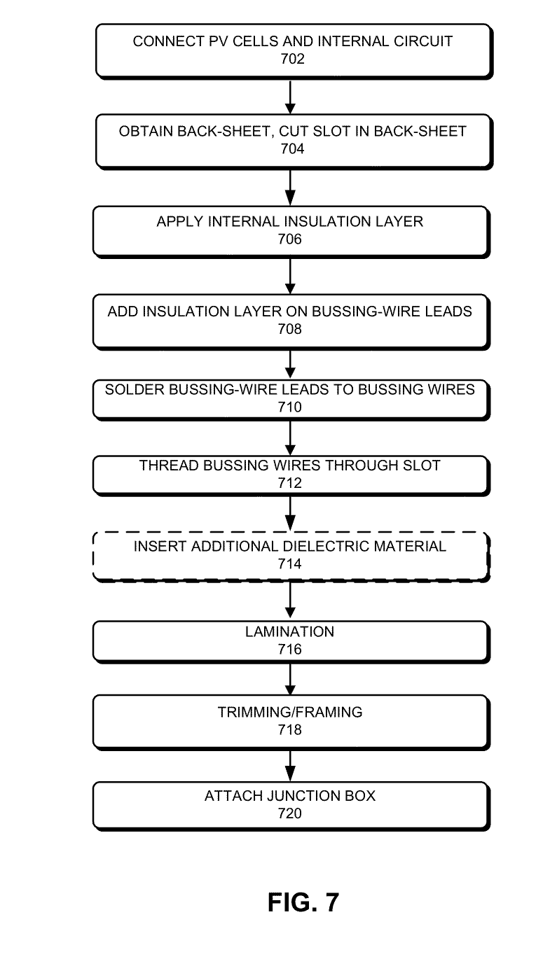

FIG. 7 presents a diagram illustrating an exemplary process of fabricating a PV module, in accordance with an embodiment of the present invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a solar module that is moisture resistant. More specifically, the solar module includes a glass front cover and an Al-based back-sheet that has a low moisture vapor transmission rate (MVTR). The Al-based back-sheet typically includes a slot to allow bussing wires to pass through to be connected to the junction box located at the back of the solar module. To minimize moisture leakage through the slot, an additional Al-based partial back-sheet can be inserted directly beneath the slot. Moreover, to prevent possible shorting of the internal circuits of the solar cells due to the Al layer included in the Al-based back-sheet, in some embodiments of the present invention, additional insulating layers, which can include insulating tapes or polyethylene terephthalate (PET) tubes, are wrapped around the bussing wires where they pass through the Al-based back-sheet. Special attention is also paid at the corners of the solar module to prevent arcing. In some embodiments, additional insulating materials (such as tapes or frame sealant) are applied at the corners. Additionally, low-MVTR materials, such as polyolefin or ionomer, can be used as encapsulant in the laminated module to ensure the moisture resistant capability of the module.

### Moisture-Resistant Solar Module

It has been shown that tunneling junction solar cells can provide superior performance because the quantum-tunneling barrier (QTB) layers can effectively passivate the surfaces of the base layer without compromising the carrier collection efficiency. FIG. 2 presents a diagram illustrating an exemplary double-sided tunneling junction solar cell, in accordance with an embodiment of the present invention. Double-sided tunneling junction solar cell 200 includes a base layer 202, quantum tunneling barrier (QTB) layers 204 and 206 covering both surfaces of base layer 202 and passivating the surface-defect states, a front-side doped a-Si layer forming a front emitter 208, a back-side doped a-Si layer forming a BSF layer 210, a front transparent conducting oxide (TCO) layer 212, a back TCO layer 214, a front metal grid 216, and a back metal grid 218. Note that it is also possible to have the emitter layer at the backside and a front surface field (FSF) layer at the front side of the solar cell. Moreover, base layer 202 can include epitaxially grown crystalline-Si (c-Si) thin film or c-Si wafers. Details, including fabrication methods, about double-sided tunneling junction solar cell 200 can be found in U.S. Pat. No. 8,686,283 (Attorney Docket No. SSP10-1002US), entitled “Solar Cell with Oxide Tunneling Junctions,” by inventors Jiunn Benjamin Heng, Chentao Yu, Zheng Xu, and Jianming Fu, filed 12 Nov. 2010, the disclosure of which is incorporated by reference in its entirety herein.

Compared with traditional diffusion-based solar cells, the tunneling junction solar cells that include a-Si and TCO layers are more susceptible to moisture. More specifically, it is well known that many TCO materials, such as ZnO or Al:ZnO, are moisture-sensitive. They may lose their material properties. For example, a ZnO film may become rough or porous when exposed to moisture for a prolonged time. On the other hand, although indium-tin-oxide (ITO) can outperform ZnO in terms of being degraded less under moisture exposure, it still experiences certain levels of degradation when exposed to both heat and moisture. Note that once the TCO film becomes porous, it allows the moisture to reach the solar cell junction, thus degrading the solar cell performance drastically.

To prevent penetration of the moisture to the solar cells, a photovoltaic (PV) module should provide moisture-resistant packaging. To assess the quality of the PV module, the International Electrotechnical Commission (IEC) and the Underwriters Laboratories (UL) standards introduce testing protocols that involve damp heat (DH) tests and humidity freeze (HF) tests. A damp heat DH1000 test specifies a 1000-hour exposure to damp heat (DH) at 85° C. and 85% relative humidity (RH). A typical HF test specifies 10 temperature cycles from −40° C. to 85° C. at 85% RH. Moreover, recent emphasis on potential induced degradation (PID), which can also be affected by heat and moisture, also puts pressure on the control of moisture ingress, because charged ions from the superstrate (such as a glass cover) would require moisture as a medium to migrate to the solar cell to degrade the quality of the solar cell junction.

To meet the IEC and/or UL standards for PV modules, the PV modules need to have reliable electrical interconnects and packaging. Due to their sensitivity to moisture, special care is needed for PV modules with TCO-based solar cells, such as the one shown in FIG. 2. Most PV modules include front and back covers that encapsulate solar cells in between. For PV modules with TCO-based solar cells, it is preferred to have the front and back covers made with materials that are resistant to moisture or with a low moisture-vapor-transmission rate (MVTR). The commonly used PV module back-sheets, which are made of polyvinyl fluoride (PVF) or polyethylene terephthalate (PET) films, are usually inadequate to meet the aforementioned IEC/UL standards for TCO-based solar cells. Therefore, it is desirable to use other encapsulation schemes that have lower MVTRs.

A possible low-MVTR packaging scheme involves using glass for both front and back covers. However, the increased weight of such modules may make them unsuitable for certain applications. For example, they may not be suitable for installation on roofs with limited load-bearing capacity. A different low-MVTR packaging approach may involve using encapsulant materials with lower MVTR, such as polyolefin. However, such an encapulant material does not have a proven 25 years of field reliability track record. A more desirable low-MVTR packaging scheme involves using a glass front cover and a back-sheet with a low MVTR, such as a back-sheet with an aluminum interlayer. The Al interlayer provides a high-quality vapor barrier. An exemplary lamination back-sheet that includes an Al interlay can be a dyMat APYE® (registered trademark of Coveme of Bologna, Italy) back-sheet. Other vendors, notably Madico Inc. of Woburn, Mass., Isovolta Group of Austria, and Dunmore Corporation of Bristol, Pa., can also provide Al-based back-sheet.

FIG. 3 presents a diagram illustrating the structure of an exemplary back-sheet with an Al interlayer. In FIG. 3, back-sheet 300 includes a plurality of layers, including a primer layer facing the solar cells, an electrical-grade PET layer, an adhesive layer between the primer layer and the electrical-grade PET layer, an Al layer, an adhesive layer between the Al layer and the electrical-grade PET layer, another PET layer that is hydrolysis resistant and UV stable, and an adhesive layer between the Al layer and the hydrolysis-resistant PET layer. Note that in the example shown in FIG. 3 the PET/Al/PET tri-layer structure provides excellent resistance to atmospheric agents, because the Al interlayer can be an outstanding moisture barrier. Moreover, the PET layers can provide excellent electrical insulation. In addition to PET, other insulating materials, such as PVF, Polyamide, and Tedlar® (registered trademark of E. I. du Pont de Nemours and Company of Wilmington, Del.), may also be used as outer layers that encapsulate the Al interlayer. However, the inclusion of an electrical conductive Al interlayer in the back-sheet can be problematic for PV modules that include discrete components connected with bussing wires, because the bussing wires may be in contact with the Al interlayer when they pass through the back-sheet to be connected to the junction box.

FIG. 4A presents a diagram illustrating the backside of a PV module. In FIG. 4A, PV module 400 includes a pair of end frames 402 and 404, a pair of side frames 406 and 408, and a junction box 410. The frames 402-408 enclose and provide support to solar cells encapsulated within the front and back covers. Junction box 410 provides connections between PV module 400 and other PV modules. In addition, junction box 410 may include other circuit components, such as bypass diodes, that are needed for operations of PV module 400. Note that, to enable compact packaging and to avoid blockage of the sunlight, junction box 410 typically resides at the backside (the side facing away from the sunlight) of PV module 400, behind the back-sheet, as shown in FIG. 4A. On the other hand, bussing wires that interconnect the solar cells (either in series on in parallel) and/or other circuit components, such as bypass diodes and maximum power point tracking (MPPT) devices, are located in front of the back-sheet. In some embodiments, the bussing wires can include tin-coated Cu wires. To enable electrical connection, the bussing wires need to pass through the back-sheet to reach junction box 410. For compact packaging, this is usually achieved by cutting an opening, such as round holes or rectangular-shaped slots, on the back-sheet, and threading the bussing wires through the opening. FIG. 4B presents a diagram illustrating a scenario where bussing wires thread through a rectangular slot on the back-sheet, in accordance with an embodiment of the present invention.

In FIG. 4B, back-sheet 420 includes a rectangular opening 422, that allows a number of bussing wires, such as bussing wires 424-432, to reach from one side (such as the frontside) of back-sheet 420 to the other side (such as the backside) of back-sheet 420. Note that bussing wires 424-432 can include, but are not limited to: the positive and negative terminals of the interconnected solar cells, terminals of the protection circuits, and terminals to other internal circuits of the PV module. Note that the number of bussing wires can vary and these bussing wires can either exit from the center of the back-sheet as shown in FIG. 4B or at any convenient location determined by the module electrical layout and the type of junction box in use. Note that IEC standard 61215 and UL standard 1703 require that a PV panel's internal circuitry and access parts should have an insulation resistance of 400 MΩ/m² tested at a voltage of (1000 Volts+2*system voltage) for Safety Class A panels. Note that the system voltage for a solar panel can be as high as 1000 Volts, meaning that the PV module needs to be tested under a voltage of 3000 Volts. This requirement can be trivial if back-sheet 420 contains only insulating materials, such as PVF or PET. However, if back-sheet 420 includes an Al interlayer, such as back-sheet 300 shown in FIG. 3, meeting the insulation requirement can be challenging, because edges or sidewalls of opening 422 may expose the internal Al layer, and shorting of the internal circuitry may occur if one or more bussing wires 424-432 come into contact with the internal Al layer. For example, bussing wires 424 and 432 may be the positive and negative terminals of the PV module, respectively. Hence, if bussing wires 424 and 432 both come into contact with the internal Al layer of back-sheet 420, then the entire PV module will be shorted.

To prevent any potential contact between the bussing wires and the Al interlayer, in some embodiments of the present invention, an additional insulation layer is introduced between the bussing wires and back-sheet 420. Various ways can be used to insert the insulation layer, including but not limited to: wrapping each individual bussing wire with an insulating tape or film, inserting each individual bussing wire into a tubing made of insulating materials (such as a PET tubing), laminating the bussing wires into one or two layers of back-sheets that contain only insulating materials, etc. Note that special attention is needed when selecting materials for the additional insulation layer to make sure that it has sufficient dielectric strength to meet the IEC and UL insulation requirements, that it is compatible with the subsequent lamination process (which may be performed under high temperature, such as around 130-150° C. for EVA-based lamination), and that it is flexible enough to survive the required DH and HF testing cycles.

In some embodiments of the present invention, one or more layers of polyimide film, such as Kapton® (registered trademark of E. I. du Pont de Nemours and Company of Wilmington, Del.) tapes, are used to wrap around each bussing wire at locations where the bussing wires may potentially be in contact with the Al interlayer. Note that the Kapton® tapes have sufficient dielectric strength and a thermal operating range that can be up to 400° C. Moreover, Kapton® tapes can maintain good adhesion during lamination; hence, they are less likely to peel off.

FIG. 5A presents a diagram illustrating a scenario where layers of dielectric tape wrap around metal bussing wires, in accordance with an embodiment of the present invention. In FIG. 5A, a back-sheet 502 includes a rectangular slot 504. A number of metal strips 506, 508, 510, 512, and 514, which are bussing wires connected to the solar cells, thread through back-sheet 502 via slot 504. From FIG. 5A, one can see that at locations where metal strips 506-514 passing through slot 504, multiple layers of dielectric tape, shown in FIG. 5A as yellow tape, wrap around each metal strip. For example, dielectric tape 516 wraps around metal strip 508 at the point where metal strip 508 passes pass through slot 504, thus preventing possible electrical contact between metal strip 508 and the Al interlayer exposed by edges or sidewalls of slot 504. In the example shown in FIG. 5A, Kapton® tapes (hence the yellow color) are used to wrap around the metal strips. Note that there can be one to ten layers of tape wrapped around the metal strips. There is a tradeoff between the dielectric strength provided by an increased number of layers and the size of slot 504. Other types of tape with high dielectric strength are also possible as long as they are able to sustain the high-temperature lamination process.

FIG. 5B presents a diagram illustrating a scenario where metal bussing wires are laminated within one or more layers of back-sheets that do not have an Al interlayer, in accordance with an embodiment of the present invention. In FIG. 5B, metal strips 522, 524, 526, 528, and 530 are pre-laminated into a partial back-sheet 532. Note that partial back-sheet 532 is called partial because it does not cover the entire backside of a solar module. To ensure reliable electrical insulation, back-sheet 532 contains only insulating materials, such as PVF, PET, and ethylene vinyl acetate (EVA). Note that EVA is used as a glue that bonds metal strips 522-530 with partial back-sheet 532. The pre-laminated metal strips can then thread through a pre-cut slot on the Al-based back-sheet with only the laminated portion in contact with edges of the pre-cut slot, thus preventing any possible shorting to the internal circuit of the PV module (not shown in FIG. 5B). In some embodiments, partial back-sheet 532 can include two back-sheet layers, metal strips 522-530 are sandwiched between the two back-sheet layers, and EVA can be used to laminate (under heat and pressure) the metal strips between the top and bottom partial back-sheet layers. The top and bottom partial back-sheet layers can include well-known insulating back-sheet materials, such as Protekt® (registered trademark of Madico, Inc. of Woburn, Mass.) and Tedlar® (registered trademark of E. I. du Pont de Nemours and Company of Wilmington, Del.).

In addition to dielectric tape and partial non-Al back-sheets, it is also possible to use insulation tubing, such as a PET tube, to slip over each individual bussing wire. Similarly, EVA can be used to bond the insulation tubing with the bussing wire. FIG. 5C presents a diagram illustrating a scenario where insulation tubing is slipped over metal bussing wires, in accordance with an embodiment of the present invention. In FIG. 5C, a back-sheet 540 includes a rectangular slot 542. A number of metal strips, such as a metal strip 544, thread through back-sheet 540 via slot 542. Insulation tubing is slipped over each bussing wire, covering portions of the metal strips. For example, insulation tubing 546 is slipped over bussing wire 544 covering a portion of bussing wire 544 that may come into contact with slot 542. In some embodiments, insulation tubing 546 can be a PET tube, and EVA is used to adhere the PET tube to the desired position. Note that the PET-EVA structure situated between the edges of slot 542 and the bussing wires ensures good electrical insulation.

In addition to the insulation problem, another problem needs to be addressed for PV modules with a back-side accessing slot cut in the back-sheet. The slot not only exposes the Al interlayer, as we have explained previously, but may also allow moisture from outside of the PV module to migrate from the back-side of the PV module to the solar cells. In the solutions shown in FIGS. 5A-5C, insulating materials (in the form of tapes, tubes, or a partial back-sheet) are introduced between the edge of the slot and the bussing wires, meaning that a wider slot is needed to accommodate such additional layers. A wider slot increases the chance of moisture ingress. In conventional PV modules, there often is an insulation patch placed at a location where the bussing wires may potentially touch the back-side of the solar cells. This particular insulation patch in the module circuit assembly not only insulates the bussing wires to the back of the solar cells, but also insulates the bussing wires to other internal circuits. FIG. 6A presents a diagram illustrating an internal circuit assembly insulation layer placed between the bussing wires and the backside of the solar cells.

FIG. 6A shows a partial view of the backside of a PV panel 600, in accordance with an embodiment of the present invention. PV panel 600 includes a plurality of inter-connected (either in parallel or in series) solar cells, such as solar cells 602 and 604. At the panel edge, the wire tabs that connect each column or row are joined together as bussing wires, such as bussing wires 606 and 608, which can be used to connect to the junction box. From FIG. 6A, one can see that because the tabs interconnecting the solar cells are joined together at the panel edge, to be connected to a junction box at the backside of the panel, the bussing wires would need to turn toward the solar cells. This arrangement makes it possible for the bussing wires to touch the backside of the solar cells, which includes backside electrodes. Hence, to provide good insulation, an insulation layer 610 (indicated by the hollow arrow) is applied to insulate between the bussing wires and at least portions of the backside of the solar cells. In conventional PV modules, insulation layer 610 is made of conventional insulating materials, such as PVF and PET. However, as discussed previously, such materials cannot effectively prevent the ingress of the moisture. As a result, the moisture may be able to migrate, via the slot on the back-sheet to the backside (note that the back-sheet and the slot are not shown in FIG. 6A), and possibly to the junction of the solar cells, degrading the solar cell performance. To prevent the ingress of the moisture through the slot on the back-sheet, in some embodiments of the present invention, insulation layer 610 includes a multi-layer insulating structure that has a low MVTR. In one embodiment, insulation layer 610 includes a PET-Al-PET structure, with the Al layer acting as a moisture barrier. In a further embodiment, insulation layer 610 can include a partial Al-based back-sheet, such as the dyMat APYE® back-sheet and Al-based back-sheet provided by other vendors, such as Madico Inc., Isovolta Group, and Dunmore Corporation.

FIG. 6B presents a diagram illustrating the side view of a PV module, in accordance with an embodiment of the present invention. In FIG. 6B, PV module 620 includes a top glass cover 622, an Al-based back-sheet 624 (which includes an Al interlayer sandwiched between at least two insulating layers), and a number of PV cells, such as cells 626 and 628. Top glass cover 622 faces the sunlight (as indicated by the arrows), and Al-based back-sheet 624 faces away from the sunlight. The PV cells are interconnected via tabbing wires, such as a tabbing wire 630. The tabbing wires connecting each row or column are joined together at the edge of PV module 620 by a number of bussing wires, such as bussing wires 632 and 634. From FIG. 6B, one can see that the PV modules and majority portions of the bussing wires are located at one side of Al-based back-sheet 624, which includes a slot 636 to allow portions of the terminal bussing wires, such as bussing wire 632 to thread through to reach to the other side of Al-based back-sheet 624.

Note that a portion of bussing wire 632 that passes through slot 636 is wrapped by an insulation layer 638, which ensures a good electrical insulation between bussing wire 632 and the Al-interlayer included in Al-based back-sheet and exposed by slot 636. Note that insulation layer 638 can include, but is not limited to: layers of tape with high dielectric strength, insulating tubes bonded with EVA, and insulating back-sheets.

PV module 620 further includes an Al-based partial back-sheet 640 situated between terminal bussing wire 632 and the backside of the PV cells. Note that, although not shown in FIG. 6B, partial back-sheet 640 extends beyond the entire length of the slot (in a direction vertical to the paper). Partial back-sheet 640 provides two services: one to provide insulation, and the other to serve as a moisture barrier. From FIG. 6B, one can see that partial back-sheet 640 insulates bussing wire 632 from the backside of the PV cells. In addition, being situated between slot 636 and the backside of the PV cells, partial back-sheet 640 blocks the continued migration of any moisture that may have entered PV module 620 via slot 636.

FIG. 6B also includes multiple layers of EVA, such as EVA layers 642, 644, and 646, which are used to bond all components in PV module 620 together during the lamination process. In fact, EVA is also used to fill in any empty spaces left between components when they are placed between front-side glass cover 622 and Al-based back-sheet 624. During lamination, under heat and pressure, EVA bonds top glass cover 622, Al-based back-sheet 624, the PV cells, other internal circuit components (such as MPPT devices), the bussing wires, and partial back-sheet 640 together to form an encapsulated stack (encapsulated between the top glass cover and the Al-based back-sheet). The encapsulated stack is then trimmed and placed inside a metal frame, forming a PV panel.

In another embodiment, instead of EVA, low-MVTR materials, such as Polyolefin (available from the 3M Company of Saint Paul, Minn.) and lonomer (available from E. I. du Pont de Nemours and Company of Wilmington, Del.) can also be used to ensure moisture ingress from the slot 636, or more importantly, from all the edges of the panel.

In addition to the insulation problem and moisture-ingress problem induced by the slot, another problem faces the PV module that implements the Al-based back-sheet. More particularly, along the edges and corners where the Al-based back-sheet is cut, the Al-interlayer may be exposed or not adequately insulated by sealant material, thus causing either shorting or arcing between the encapsulated stack and the metal frame of the PV module. This problem is generally more severe at corners than at the edges because at the four corners the frame sealant tends to spread thinner at the corner in order for the encapsulated stacks to fit snugly in the frame. The inadequate application of the frame sealant, which supposedly serves as both an insulation layer and a moisture blocker, can cause the PV panel to fail the IEC 61215/UL1703 insulation test, which requires Safety Class A panels to have an insulation resistance of 400 MΩ/m² tested at a voltage of (1000 Volts+2*system voltage). This issue is made worse if the Al frames are shorted to the Al-based back-sheet, causing a large potential drop between the bussing wires and the slotting area in the back-sheet, which makes it more important to ensure good insulation around the bussing wire at the slot area. In addition, the possible arcing due to discharge between the corners or edges of the Al-based back-sheet and the metal frame raises the concern of fire hazards.

To address this corner/edge problem, special care is needed to make sure that the frame sealant is adequately applied. In some embodiments of the present invention, the metal frame holding the laminated layer stack is enlarged (compared with the conventional PV modules) to ensure that sufficient sealant can flow to all corners. For example, one may need to make sure that there is a predetermined minimum distance between the metal frame and edges and/or corners of the laminated layer stack to ensure that insulation material (such as sealant) of a pre-determined thickness can be inserted between the meal frame and the laminated layer stack. In some embodiments, the minimum distance may be between 1 and 3 mm. In some embodiments, one or more layers of dielectric tape, such as Kapton® tapes or other types of tape, are wrapped around the corners of the laminated stacks to ensure sufficient insulation between the back-sheet and the metal frame.

FIG. 7 presents a diagram illustrating an exemplary process of fabricating a PV module, in accordance with an embodiment of the present invention. During fabrication, the fabricated solar cells and possible internal circuit components are properly connected via tabbing wires, and the tabbing wires from different rows/columns are joined together by bussing wires (operation 702). A back-sheet with an Al-interlayer, such as the dyMat APYE® back-sheet, is selected and a slot with a predetermined size is cut in a pre-determined location in the back-sheet (operation 704). Note that the slot needs to be long enough to accommodate all passing bussing wires. In some embodiments, the slot is between 55 and 60 mm long. The slot also needs to be slightly wider than the sum of the thickness of the bussing wire and the additional insulating layers wrapped around the bussing wires. The location of the slot is determined based on the location of the junction box on the backside of the PV module. In some embodiments, the slot can be placed at various locations on the back-sheet depending on the electrical layout of the PV module and the type of junction box in use.

When assembling the PV module, an internal insulation layer with low MVTR is applied between the backside of the PV cells and the bussing wires (operation 706). In some embodiments, the internal insulation layer includes EVA and an Al-based back-sheet material, such as the dyMat APYE® back-sheet. The insulation layer is placed directly above the slot on the back-sheet to prevent possible moisture ingress from the slot.

Subsequently, bussing-wire leads that connect the bussing wires of the solar cell internal circuit assembly and the junction box are prepared, which involves adding additional insulation layers to the bussing-wire leads at locations where the bussing wires may contact the slot edge (operation 708). In some embodiments, tape with high dielectric strength is wrapped around portions of the bussing wires. In some embodiments, one or more layers of back-sheet materials (non-metal based) are pre-laminated onto portions of the bussing wires. In some embodiments, insulating tubes with EVA insertions are slipped on the bussing wires, and are bonded to the bussing wires by the EVA insertions.

Once the additional insulation layers are in place, the bussing-wires leads can be soldered to the bussing wires of the internal circuit assembly (operation 710), and are threaded through the slot to connect to the junction box located at the backside of the PV module (operation 712). Optionally, additional dielectric material can be inserted in the slot, filling any voids left between the bussing wires and the slot, to achieve more robust insulation (operation 714). A lamination process is then performed (operation 716), followed by subsequent trimming and framing of the laminated stack (operation 718), and connection to the junction box (operation 720) to finish the rest of the module fabrication.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A photovoltaic (PV) module, comprising:
a front-side glass cover facing sunlight;
a plurality of interconnected PV cells situated below the glass cover;
a plurality of bussing wires electrically coupled to the PV cells;
a back-sheet situated below the PV cells, wherein the back-sheet comprises a metal layer sandwiched between a top insulation layer and a bottom insulation layer, wherein the back-sheet comprises a cut slot to facilitate the bussing wires to thread through the cut slot to reach a junction box situated below the back-sheet; and
one or more insulation layers inserted between the bussing wires and sidewalls of the cut slot in the back-sheet, wherein the insulation layers are configured to insulate the bussing wires to the metal layer in the back-sheet.

2. The PV module of claim 1, wherein the insulation layers in the back-sheet include one or more of: polyethylene terephthalate (PET), Fluoropolymer, polyvinyl fluoride (PVF), and polyamide; and wherein the metal layer in the back-sheet comprises Al.

3. The PV module of claim 2, wherein the back-sheet includes one or more of:
a dyMat APYE® back-sheet made by Coveme;
a Protekt® back-sheet made by Madico, Inc.; and
an Al-based back-sheet made by Isovolta Group or Dunmore Corporation.

4. The solar cell of claim 1, wherein the one or more insulation layers include at least one of:
dielectric tape;
a tube made of dielectric materials;
a non-metal partial back-sheet; and
a partial back-sheet with a metal interlayer.

5. The PV module of claim 4, wherein the dielectric tape includes Kapton® tape.

6. The PV module of claim 4, wherein the tube includes at least one of:
a polyethylene terephthalate (PET) tube; and
a polyvinyl fluoride (PVF) tube.

7. The PV module of claim 4, wherein the non-metal partial back-sheet includes a Protekt® back-sheet or a Tedlar® back-sheet.

8. The PV module of claim 1, further comprising an additional partial back-sheet situated between the PV cells and bussing wires at a location where the bussing wires thread through the cut slot, wherein the additional partial back-sheet includes a metal interlayer situated between a top insulation layer and a bottom insulation layer, and wherein the additional partial back-sheet is configured to:
insulate the bussing wires to a backside of the solar cells; and
block potential moisture ingress from the cut slot in the back-sheet.

9. The PV module of claim 8, wherein the additional partial back-sheet includes an Al interlayer.

10. The PV module of claim 1, wherein the PV cells include at least one double-sided tunneling junction solar cell.

11. The PV module of claim 1, wherein the PV cells and the bussing wires are encapsulated between the front-side glass cover and the back-sheet during a lamination process, forming a laminated structure.

12. The PV module of claim 11, wherein encapsulating the PV cells and the bussing wires involves using a low moisture vapor transmission rate (MVTR) encapsulant that comprises one or more of: polyolefin and ionomer.

13. The PV module of claim 11, further comprising a metal frame configured to hold the laminated structure.

14. The PV module of claim 13, wherein the metal frame is sufficiently large to ensure a predetermined minimum distance is maintained between corners and edges of the laminated structure and the metal frame, thereby facilitating application of insulation materials with sufficient thickness.

15. The PV module of claim 13, wherein corners of the laminated structure are wrapped with one or more layers of dielectric tape.

16. The PV module of claim 1, wherein the PV cells include one or more of:
a transparent conducting oxide (TCO) layer acting as an electrode; and
an anti-reflecting coating (ARC) layer.

17. A method for fabricating a PV module, comprising:
obtaining a front-side glass cover;
obtaining a plurality of interconnected PV cells;
coupling the PV cells to a plurality of bussing wires;
obtaining a back-sheet, wherein the back-sheet comprises a metal layer sandwiched between a top insulation layer and a bottom insulation layer;
placing the PV cells and the bussing wires between the front-side glass cover and the back-sheet;
cutting a slot in the back-sheet;
applying one or more insulation layers around the bussing wires; and
threading the bussing wires through the cut slot in the back-sheet to reach a junction box situated below the back-sheet, wherein the applied one or more insulation layers are situated between the bussing wires and sidewalls of the cut slot in the back-sheet to insulate the bussing wires to the metal layer in the back-sheet.

18. The method of claim 17, wherein the insulation layers in the back-sheet include one or more of: polyethylene terephthalate (PET), Fluoropolymer, polyvinyl fluoride (PVF), and polyamide; and wherein the metal layer in the back-sheet comprises Al.

19. The method of claim 17, wherein the back-sheet includes one or more of:
a dyMat APYE® back-sheet made by Coveme;
a Protekt® back-sheet made by Madico, Inc.; and
an Al-based back-sheet made by Isovolta Group or Dunmore Corporation.

20. The method of claim 17, wherein the one or more insulation layers include at least one of:
dielectric tape;
a tube made of dielectric materials;
a non-metal partial back-sheet; and
a partial back-sheet with a metal interlayer.

21. The method of claim 20, wherein the dielectric tape includes Kapton® tape.

22. The method of claim 20, wherein the tube includes at least one of:
a polyethylene terephthalate (PET) tube; and
a polyvinyl fluoride (PVF) tube.

23. The method of claim 20, wherein the non-metal partial back-sheet includes a Protekt® back-sheet or a Tedlar® back-sheet.

24. The method of claim 17, further comprising inserting an additional partial back-sheet situated between the PV cells and bussing wires at a location where the bussing wires thread through the cut slot, wherein the additional partial back-sheet includes an Al interlayer situated between a top insulation layer and a bottom insulation layer, and wherein the additional partial back-sheet is configured to:
insulate the bussing wires to a backside of the solar cells; and
block potential moisture ingress from the cut slot in the back-sheet.

25. The method of claim 17, wherein the PV cells include at least one double-sided tunneling junction solar cell.

26. The method of claim 17, further comprising performing a lamination process to encapsulate the PV cells and the bussing wires between the front-side glass cover and the back-sheet, thereby forming a laminated structure.

27. The method of claim 26, wherein the lamination process involves using a low moisture vapor transmission rate (MVTR) encapsulant that comprises one or more of: polyolefin and ionomer.

28. The method of claim 26, further comprising placing the laminated structure in a metal frame.

29. The method of claim 28, wherein the metal frame is sufficiently large to ensure a predetermined minimum distance is maintained between corners and edges of the laminated structure and the metal frame, thereby facilitating application of insulation materials with sufficient thickness.

30. The method of claim 28, further comprising wrapping corners of the laminated structure with one or more layers of dielectric tape.

31. The method of claim 17, wherein the PV cells include one or more of:
a transparent conducting oxide (TCO) layer acting as an electrode; and
an anti-reflecting coating (ARC) layer.
